(19) United States
(12) Patent Application Publication
(10) Pub. No.: US 2008/0237670 A1
(43) Pub. Date: Oct. 2, 2008

(54) Light receiving element

(75) Inventor: Akihiro Hasegawa, Hashima-shi (JP)

Correspondence Address: OLIFF & BERRIDGE, PLC, P.O. BOX 320850, ALEXANDRIA, VA, 22320-4850, US

(73) Assignees: SANYO ELECTRIC CO., LTD., MORIGUCHI-SHI (JP); SANYO SEMICONDUCTOR CO., LTD., ORA-GUN (JP)

(21) Appl. No.: 12/076,500

(22) Filed: Mar. 19, 2008

(30) Foreign Application Priority Data
Mar. 27, 2007 (JP) 2007-082433

(51) Int. Cl. H01L 31/062

(52) U.S. Cl. 257/292; 257/E31.001

(57) ABSTRACT

A structure is provided in a light receiving element having a plurality of light receiving regions, in which noise charges from other light receiving regions to the signal charges of each light receiving region are prevented from becoming superimposed, and each light receiving region can generate accurate electric current signals. The structure is provided with a first light receiving region and a second light receiving region, which are formed on a semiconductor substrate having a first conductivity, and a drain region, which is formed on the semiconductor substrate having a second conductivity. Each light receiving region has at least one light receiving unit that is divided into a plurality of segments and that outputs electric currents corresponding to incident light. The drain region is formed between the first light receiving region and the second light receiving region.

### CROSS-REFERENCE TO RELATED APPLICATION

The priority application number JP2007-082433 upon which this patent application is based is hereby incorporated by the reference.

### BACKGROUND OF THE INVENTION

1. Field of the Invention

The present invention relates to a light receiving element provided with a plurality of light receiving regions having light receiving units divided into a plurality of segments.

2. Description of the Related Art

FIG. 1 shows a flat surface configuration of a conventional light receiving element 170. The light receiving element 170 has a first light receiving region 72 and a second light receiving region 78. The first light receiving region 72 is composed of a first main light receiving unit 72-1 and first auxiliary light receiving units 72-2 and 72-3. A first main light receiving unit 72-1 is positioned between the first auxiliary light receiving units 72-2 and 72-3. The second light receiving region 78 also has a second main light receiving unit 78-1 and second auxiliary light receiving units 78-2 and 78-3 in same manner the first light receiving region 72, and the second main light receiving unit 78-1 is disposed between the second auxiliary light receiving units 78-2 and 78-3. The structure of each of these light receiving units is as disclosed in Japanese Laid-open Patent Application No. 2006-332104.

FIG. 2 shows the cross-sectional configuration of the conventional light receiving element 170. FIG. 2 shows the cross-sectional configuration along the line A-A′ shown in FIG. 1. The light receiving element 170 is formed using a semiconductor substrate on which an epitaxial layer 92, having a lower impurity concentration and a higher resistivity than a P-sub layer 90, is layered on a P-sub layer 90, which is a p-type silicon substrate to which p-type impurities have been introduced. A P-sub layer 90 is composed of a silicon substrate into which boron or other p-type impurities have been introduced. An epitaxial layer 92 is formed on the silicon substrate that constitutes the P-sub layer 90 by epitaxially growing silicon. A cathode region 82 in which n-type impurities are dispersed is formed in the surface of the epitaxial layer 92. The P-sub layer 90, the epitaxial layer 92, and the cathode region 82 constitute a PIN photo diode (PD) 76 in which the p-type P-sub layer 90 acts as the anode region and the n-type cathode region 82 acts as the cathode region.

A separation region 80 is formed on the surface of the epitaxial layer 92 by introducing p-type impurities. The separation region 80 is disposed so that the plurality of cathode regions 82 is divided. The light receiving element 170 outputs electric current signals that are read out from the plurality of cathode regions 82 which are divided by the separation region 80. The electric current signal thus read out from the plurality of cathode regions 82 undergoes current/voltage conversion or signal amplitude processing by using the circuit element group that is formed but not shown on the periphery of the first light receiving region 72 and the second light receiving region 78.

As mentioned above, the structure of the PD 76 on the surface of the semiconductor substrate is formed and the wiring structures and a passivation layer and the like are formed thereafter on the semiconductor substrate. For example, an antireflective coating 126 is layered on the surface of the substrate, a first interlayer insulation film 130 is layered, a wiring layer 138 composed of a metallic film is layered, and a second interlayer insulation film 136 is layered.

The light receiving element 170 may be used in optical pickup for the recording and playback of DVDs, CDs, and other optical discs. The first and second light receiving regions 72 and 78 receive light reflected from laser light outputted from the optical pickup and generate electric current signals. The electric current signals generated by using the first and second main light receiving units 72-1 and 78-1 are inputted to a signal processing circuit. The signal processing circuit performs demodulation processing and decoding processing and plays back digital data from the inputted electric current signals. The electric current signals generated by using the first and second auxiliary light receiving units 72-2, 72-3, 78-2, and 78-3 are used to control the operation of the optical pickup. Specifically, a tracking error signal is generated from the outputted signals of the auxiliary light receiving units. An optical disc recording/playback apparatus provided with an optical pickup controls the optical pickup so that it follows the recorded track formed on the optical disc on the basis of the tracking error signal.

The first light receiving region 72 and the second light receiving region 78 are provided for recording and playing back two mutually different types of optical discs. For example, the first light receiving region 72 is provided for recording and playing back DVDs, and the second light receiving region 78 is provided for recording and playing back CDs. Reflected light of the laser light will be incident on the first light receiving region 72 during recording and playing back a DVD, and reflected light of the laser light will be incident on the second light receiving region 78 when recording and playing back a CD. In this case, the interspacing between the first main light receiving unit 72-1 and the auxiliary light receiving units 72-2 and 72-3 included in the first light receiving region 72 is set to be smaller than the interspacing between the second main light receiving unit 78-1 and the auxiliary light receiving units 78-2 and 78-3 included in the second light receiving region 78.

The first light receiving region 72 and the second light receiving region 78 provided to the light receiving element 170 receive reflected light of the laser light via an optical lens, which is not shown. For example, the first light receiving region 72 is alternatively operated and reflected light of the laser light is received by the first light receiving region 72 when recording and playing back a DVD. At this time, the reflected light is incident not only on the first light receiving region 72 but also on the second light receiving region 78 due to light dispersion by the optical lens and other effects, and signal charges are generated.

The signal charges generated in the second light receiving region 78 are essentially held by the second light receiving region 78 because the first light receiving region 72 and the second light receiving region 78 are separated by the separation region 80. However, part of the signal charges generated in the second light receiving region 78 occasionally crosses over the separation region 80 because the second light receiving region 78 is in a floating state when the first light receiving region 72 is operated and the reflected light of the laser is received. For example, part of the signal charges generated by the PDs 76-1 and 76-2 included in the second light receiving region 78 may cross over the separation region 80 and move to the PDs 76-3 and 76-4 included in the first light receiving region 72 and are superimposed as noise charges on the signal charges of these PDs 76-3 and 76-4. At this time, the PDs 76-3 and 76-4 included in the first light receiving region 72 output a signal current on the basis of the sum of the signal charges generated in the first light receiving region 72 and the noise charges generated in the second light receiving region 78.

For the reason listed above, the PDs 76-3 and 76-4 which are included in the first light receiving region are more susceptible to the effects of noise charges in comparison with the PDs 76-1 and 76-2 included in the first light receiving region 72. This can result in the problem of inaccurate control of the optical pickup carried out on the basis of the electric current signal output by the first light receiving region 72. Also, there is a similar problem when the second light receiving region 78 is used.

### SUMMARY OF THE INVENTION

In view of the above-described prior art, it is an object of the present invention to provide a light receiving element which can prevent the superimposition of noise charges and generate accurate electric current signals even where provided with a plurality of light receiving regions.

The present invention comprises a first light receiving region, which is formed on a semiconductor substrate having a first conductivity, and which has at least one light receiving unit that is divided into a plurality of segments and that outputs electric currents corresponding to incident light; a second light receiving region, which is formed on the semiconductor substrate, and which has at least one light receiving unit that is divided into a plurality of segments and that outputs electric currents corresponding to the incident light; and a drain region, which has a second conductivity that is different from the first conductivity, which is formed on the semiconductor substrate, and which is formed between the first light receiving region and the second light receiving region.

### BRIEF DESCRIPTION OF THE DRAWINGS

FIG. 1 is a schematic plan view of a conventional light receiving element;

FIG. 2 is a schematic cross-sectional view showing the structure of a conventional light receiving element;

FIG. 3 is a schematic plan view of the light receiving element in an embodiment of the present invention;

FIG. 4 is a plan view of the first main light receiving unit in an embodiment of the present invention; and

FIG. 5 is a schematic cross-sectional view of the structure of the light receiving element in an embodiment of the present invention.

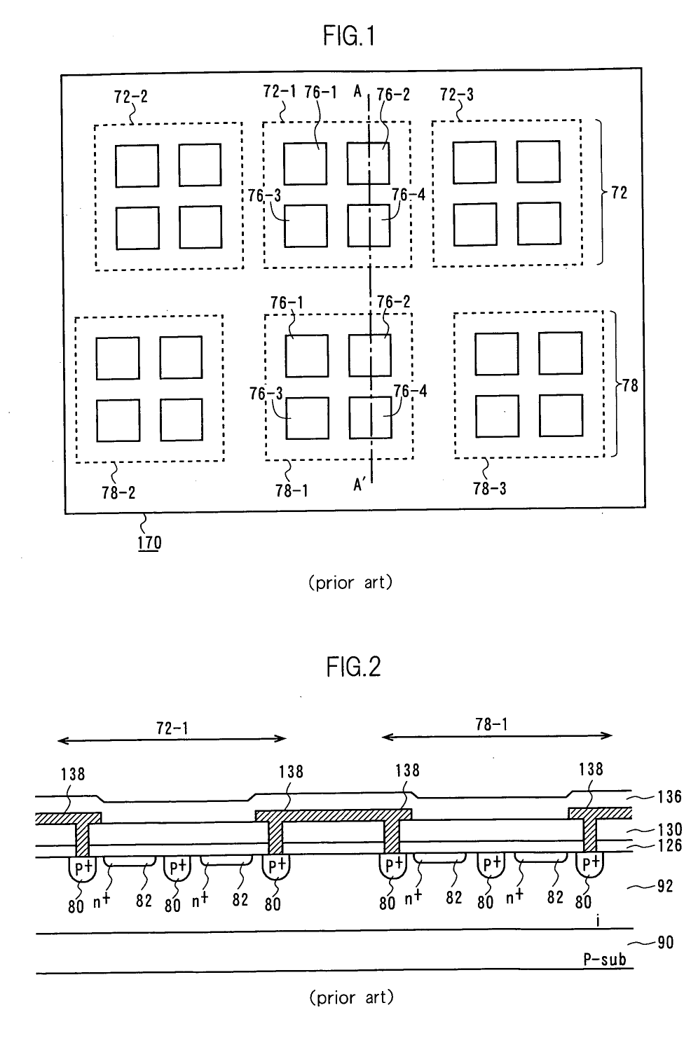

### DESCRIPTION OF THE PREFERRED EMBODIMENTS

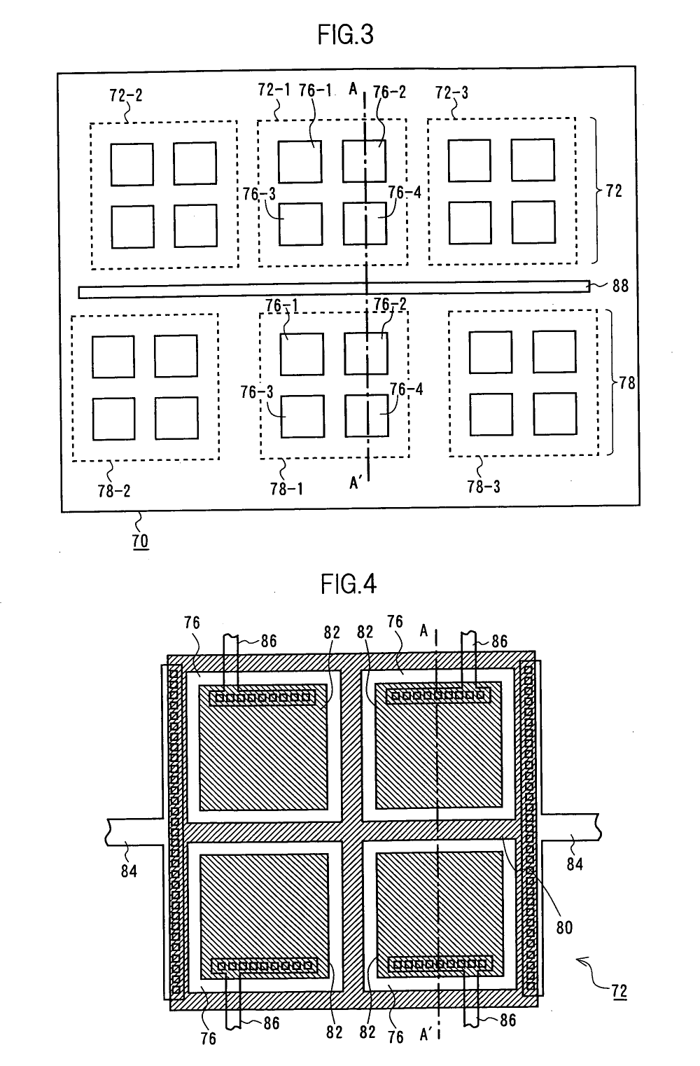

FIG. 3 is a schematic plan view of the light receiving element in an embodiment of the present invention. The light receiving element 70 is formed on a semiconductor substrate composed of silicon and is composed of a first light receiving region 72 and a second light receiving region 78.

The first light receiving region 72, for example, includes a first main light receiving unit 72-1 and first auxiliary light receiving units 72-2 and 72-3, each having four PIN photo diodes (PD) arrayed in a 2×2 grid and receives light from the optical system incident on the substrate surface, the light having been divided into four segments of a 2×2 grid in each light receiving unit. The first main light receiving unit 72-1 is disposed between the first auxiliary light receiving units 72-2 and 72-3. A second light receiving region 78 includes a second main light receiving unit 78-1 and second auxiliary light receiving units 78-2 and 78-3, each having four PDs 76 in the same fashion as the first light receiving region 72. The second main light receiving unit 78-1 is disposed between the second auxiliary light receiving units 78-2 and 78-3. The interspacing between the first main light receiving unit 72-1 and first auxiliary light receiving units 72-2 and 72-3, which are included in the first light receiving region 72, is set to be smaller than the interspacing between the second main light receiving unit 78-1 and second auxiliary light receiving units 78-2 and 78-3, which are included in the second light receiving region 78. A drain region 88 is disposed between the first light receiving region 72 and the second light receiving region 78 so as to separate the two.

The light receiving element 70 can be used for optical pickup to perform the recording and playback of DVDs, CDs, and other optical discs in the same fashion as light receiving elements 170 of the prior art described above. The first and second light receiving regions 72 and 78 receive reflected light of the laser light outputted from the optical pickup and generate electric current signals. The electric current signals generated by using the first and second main light receiving units 72-1 and 78-1 are inputted to the signal processing circuit. The signal processing circuit performs demodulation processing and decoding processing, and plays back digital data from the inputted electric current signal. The electric current signals generated by using the first and second auxiliary light receiving units 72-2, 72-3, 78-2, and 78-3 are used to control the operation of the optical pickup. Specifically, a tracking error signal is generated from the outputted signal of the auxiliary light receiving units. An optical disc recording and playback apparatus provided with an optical pickup controls the optical pickup so that it follows the recorded track formed on the optical disc on the basis of the tracking error signal.

FIG. 4 is a more detailed plan view of an example of the first main light receiving unit 72-1. The PDs 76-1, 76-2, 76-3, and 76-4 are divided from each other by a separation region 80 that is formed on the surface of the semiconductor substrate of the periphery of the PDs. For example, a p⁺ region in which high concentration of p-type impurities has been dispersed is formed as the separation region 80. Electrons or positive holes are generated by the absorption of light in the portion that corresponds to the light receiving unit of the silicon substrate. A cathode region 82 that collects electrons from the generated electrical charges is disposed as a cathode in each PD 76. For example, an n⁺ region in which a high concentration of n-type impurities is dispersed is formed as the cathode region 82.

The cathode region 82 is connected to wiring 86 formed using, e.g., an Al layer or the like via a contact. For example, a ground potential is applied to the separation region 80 via wiring 84 that extends from adjoining regions. Also, the signal charges collected in the cathode regions 82 are read out to a signal processing circuit (not shown) via the wiring 86. For example, the electric current signals read out from the cathode regions 82 are converted to voltage signals by a current detector and thereafter amplified in an amplification circuit.

The configurations of the first auxiliary light receiving units 72-2 and 72-3, the second main light receiving unit 78-1, and the second auxiliary light receiving units 78-2 and 78-3 are the same as the configuration of the first main light receiving unit 72-1 shown in FIG. 4.

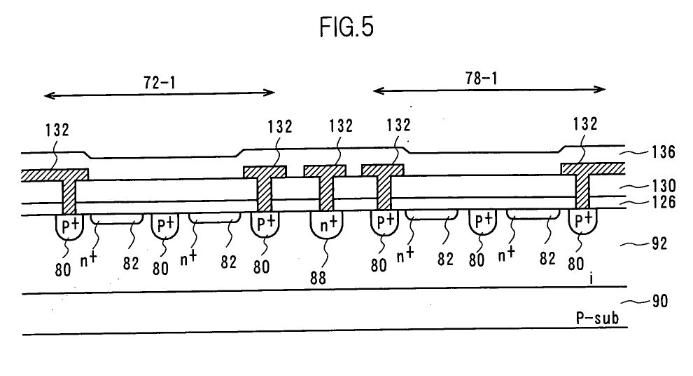

FIG. 5 is a schematic cross-sectional view showing the structure of the light receiving element 70 on a cross-section that is perpendicular to the semiconductor substrate along the line A-A′ shown in FIGS. 3 and 4. Shown in the cross-section are PDs 76-2 and 76-4 of the first main light receiving unit 72-1, the drain region 88, PDs 76-2 and 76-4 of the second main light receiving unit 78-1, wiring and an interlayer insulation film which are layered on the semiconductor substrate in which the above components are formed, and other structures.

The light receiving element 70 is formed using a semiconductor substrate that is obtained by layering an epitaxial layer 92 having a lower concentration of impurities and higher specific resistance than the P-sub layer 90 onto a P-sub layer 90, which is a p-type silicon substrate into which p-type impurities have been introduced. The P-sub layer 90 is constitutes an anode that is shared by each PD 76, and a ground potential, e.g., is applied from the underside of the substrate. The separation region 80 has a ground potential applied thereto via the wiring 84 that is provided to the front surface side of the substrate described above, and constitutes an anode together with the P-sub layer 90.

The epitaxial layer 92 is configured with an i-layer of each PD 76 of the first main light receiving unit 72-1 and the second main light receiving unit 78-1. The low concentration impurities introduced into the epitaxial layer 92 are, for example, p-type impurities. The thickness of the epitaxial layer 92 is set to be equal to or greater than about the absorption length in the semiconductor of the light to be detected. For example, the absorption length of silicon in relation to the 780-nm band or 650-nm band used in CDs or DVDs is about 10 to 20 μm. Therefore the thickness of the epitaxial layer 92 in this case set to 10 to 20 μm. The above-described separation region 80 and cathode region 82 are formed on the surface of the epitaxial layer 92 in the first main light receiving unit 72-1 and the second main light receiving unit 78-1.

The drain region 88 is formed in a position between the first main light receiving unit 72-1 and the second main light receiving unit 78-1 on the surface of the epitaxial layer 92. The drain region 88 is, for example, formed as an n⁺ region in which a high concentration of n-type impurities have been dispersed and has a predetermined electric potential, e.g., +3V applied from the wiring layer 132. The drain region 88 captures electric charges that exist near a periphery thereof and reduces the flow of noise charges from the first main light receiving unit 72-1 to the second main light receiving unit 78-1 and the flow of noise charges from the second main light receiving unit 78-1 to the first main light receiving unit 72-1.

The structures of the PD 76 and the drain region 88 in the surface of the semiconductor substrate are formed in the manner described above, and the wiring structure, insulation films, and the like are thereafter formed on the semiconductor substrate. For example, an antireflective coating 126 is layered on the surface of the substrate, a first interlayer insulation film 130 is layered, a wiring layer 138 composed of a metallic film is layered, and a second interlayer insulation film 136 is layered. For example, the wiring 86 shown in FIG. 4 is formed using the wiring layer 132.

For example, due to the effect of the dispersion of light by the optical lens or other effects, the reflected light is incident not only on the first light receiving region 72 but also on the second light receiving region 78, and signal charges are generated when an optical disc is being recorded and played back using the first light receiving region 72. At this time, part of the signal charges generated in the second light receiving region 78 attempt to cross over the separation region 80 provided to the second light receiving region 78 and move into the first light receiving region 72. However, in the embodiment of the present invention, the charges that cross over the separation region 80 provided to the second light receiving region 78 are trapped in the drain region 88 because the drain region 88 is disposed between the first light receiving region 72 and the second light receiving region 78. For this reason, the charges generated in the second light receiving region 78 can be prevented from moving to the first light receiving region 72 and becoming superimposed as noise charges onto the signal charges of the first light receiving region 72, and the first light receiving region 72 can generate accurate electric current signals in accordance with the intensity of the reflected light. Also, the same effect can be obtained even when an optical disc is recorded and played back using the second light receiving region 78.

In addition, in the embodiment of the present invention, the configuration is one in which a ground potential is applied to the P-sub layer 90, the separation region 80, and the cathode region 82, but the present invention is not limited to this configuration. It would be possible to apply different potentials to the P-sub layer 90, to the separation region 80, and to the drain region 88, depending on the region.

Also, in the embodiment of the present invention, a configuration is used in which a predetermined positive potential (+3 V) is applied to the drain region 88, but the present invention is not limited to this configuration. For example, a ground potential or a predetermined negative potential may be advantageously applied to the drain region 88 in the case that an n-type semiconductor substrate is used and the cathode region 82 is a p⁺ region, the separation region 80 is an n⁺ region, the drain domain 88 is a p⁺ region.

In accordance with the present invention as described above, the light receiving element can prevent the superimposition of noise charges and generate an accurate electric current signal even when a plurality of light receiving regions are provided.

What is claimed is:

1. A light receiving element comprising:
a first light receiving region, which is formed on a semiconductor substrate having a first conductivity, and which has at least one light receiving unit that is divided into a plurality of segments and that outputs electric currents corresponding to incident light;
a second light receiving region, which is formed on the semiconductor substrate, and which has at least one light receiving unit that is divided into a plurality of segments and that outputs electric currents corresponding to the incident light; and
a drain region, which has a second conductivity that is different from the first conductivity, which is formed on the semiconductor substrate, and which is formed between the first light receiving region and the second light receiving region.

2. The light receiving element according to claim 1, wherein
the first light receiving region includes a plurality of light receiving units; and
the second light receiving region includes a plurality of light receiving units.

3. The light receiving element according to claim 2, wherein the interspacing between the plurality of light receiving units included in the first light receiving region is smaller than the interspacing between the plurality of light receiving units included in the second light receiving region.

4. The light receiving element according to claim 1, wherein the light receiving unit has:
an intermediate semiconductor region having a low impurity concentration disposed on the main surface of the semiconductor substrate;
a lower semiconductor region of a first conductivity having a higher impurity concentration than the intermediate semiconductor region, wherein the region is disposed in contact with a lower surface of the intermediate semiconductor region, and is impressed with a first voltage;
a separation region of a first conductivity having a higher impurity concentration than the intermediate semiconductor region, wherein the region is formed on a surface of the intermediate semiconductor region along interfaces between the segments, and is impressed with a second voltage; and
a plurality of upper semiconductor regions of a second conductivity having a higher impurity concentration than the intermediate semiconductor region, wherein the regions are formed on the surface of the intermediate semiconductor region at locations respectively corresponding to the segments, and are impressed with a third voltage;
and wherein the upper semiconductor regions and the lower semiconductor region are placed in a state of inverse bias by the first and third voltages, and form a depletion layer in the intermediate semiconductor region; and the separation region forms an electric potential barrier against the migration of the signal charges between the segments to the lower semiconductor regions in accordance with the second voltage.

5. The light receiving element according to claim 4, wherein a fixed voltage is applied to the drain region.
